(19) United States
(12) Patent Application Publication
(10) Pub. No.: US 2022/0058325 A1
(43) Pub. Date: Feb. 24, 2022

(54) Method for Recognizing Analog Circuit Structure

(71) Applicant: AnaGlobe Technology, Inc., Hsinchu City (TW)

(72) Inventors: Po-Hung Lin, Hsinchu County (TW); Zheng-Yao Liu, New Taipei City (TW); Jun-Jie Zhao, Taichung City (TW); Yu-Tsang Hsieh, Hsinchu County (TW)

(21) Appl. No.: 16/996,540

(22) Filed: Aug. 18, 2020

(51) Int. Cl. G06F 30/373; G06K 9/62; G06N 20/00

(52) U.S. Cl. CPC G06F 30/373; G06N 20/00; G06K 9/6256

(57) ABSTRACT

A method for recognizing various analog circuit structures is proposed, which is executed by a computer, the method comprising using the computer to perform the following: performing a feature extraction of a training circuit to extract all sub-circuits for generating multiple training samples; classifying multiple training samples by a classifier to obtain classified building blocks; performing a feature extraction of each schematic of a target circuit to convert as a feature graph and encoding feature graph as a feature matrix; classifying feature matrix by the classifier to generate multiple groups of classified devices; and clustering multiple groups of classified devices to acquire identified sub-circuits.

### TECHNICAL FIELD

The present invention relates to an analog circuit recognition technique, and more particularly, to a method for recognizing various analog circuit structures.

### BACKGROUND

Analog circuit designs are quite different from digital circuit designs from a layout perspective. Unlike a large-scale digital design, an analog circuit design usually has a relatively small scale, i.e., an analog circuit typically has a relatively small die size. However, its physical behavior is very sensitive to the layout geometry, e.g., parasitic coupling effect, small signal transmission, wiring crossovers, etc. Hence, area minimization is usually not a concern for an analog circuit design. A digital circuit designer can leverage mature commercial electronic design automation (EDA) tools to automate layout generation. However, the existing and popular way to generate an analog circuit layout is far from automatic. The manual, time-consuming, error-prone task highly depends on the layout designer's experience and wit. However, analog circuit design automation has become desirable.

Traditionally, analog circuitry has been manually laid out into its semiconductor mask layers for semiconductor manufacturing. This is because a human layout designer typically was experienced in analog circuit layout with prior knowledge, experience, and skill as to how the devices in an analog circuit were laid out so as to provide better performance and/or better noise immunity. The human layout designer can make some choices up front prior to laying out the analog circuitry. However, the number of choices that can be made up-front prior to layout by a human layout designer are limited. Moreover, a human layout designer requires considerable time to layout an entire analog circuit chip.

The traditional approach might not be sufficient for solving the problem effectively. Therefore, the invention proposes a new approach resulting in runtime improvement without sacrificing accuracy.

### SUMMARY OF THE INVENTION

In this invention, a method for recognizing various analog circuit structures is proposed, which is executed by a computer, the method comprising using the computer to perform the following: performing a first feature extraction of a training circuit to extract all sub-circuits for generating multiple training samples; classifying the multiple training samples by a classifier to obtain classified building blocks; performing a second feature extraction of each schematic of a target circuit to convert as a feature graph and encoding the feature graph as a feature matrix; classifying the feature matrix by the classifier to generate multiple groups of classified devices based on the classified building blocks; and clustering the multiple groups of classified devices to acquire identified sub-circuits.

According to one aspect, the method further comprises storing the classified building blocks in a sub-circuit library.

According to another aspect, the classifier is used to automatically identify a type of each of all building blocks.

According to one aspect, the multiple training samples comprises a feature matrix and a label matrix, and the classifier is utilizing a classified model to classify the multiple training samples in a training sample set. The classified model includes decision tree, neural network. The classified model is performed by a machine learning algorithm. The machine learning algorithm includes a feature extraction process and the classified model.

According to one aspect, the encoded feature graph is indicated by a number, and encoded feature graph with the number is one-to-one mapping.

In the invention, a non-transitory computer-readable medium containing instructions is proposed, which when read and executed by a computer, cause the computer to execute a method for recognizing various analog circuit structures, wherein the method comprises the above-mentioned steps.

### BRIEF DESCRIPTION OF THE DRAWINGS

The components, characteristics and advantages of the present invention may be understood by the detailed descriptions of the preferred embodiments outlined in the specification and the drawings attached:

FIG. 1 shows a schematic diagram of a method for recognizing various analog circuit structures;

FIG. 2 shows an exemplary CMOS cascade operational transconductance amplifier (OTA);

FIG. 3 illustrates an analog building block recognition corresponding to FIG. 2;

FIG. 4 shows a connection graph representation for the OTA in FIG. 2;

FIG. 5 shows the encoded features of each sub-circuits;

FIG. 6 illustrates the encoded features of each sub-circuits;

FIG. 7 shows the schematic and the feature graph of 4 transistor current mirror (4TCM);

FIG. 8 illustrates a feature matrix of 4 transistor current mirror (4TCM);

FIG. 9 illustrates a device clustering; and

FIG. 10 illustrates an example of device clustering.

### DETAILED DESCRIPTION

Some preferred embodiments of the present invention will now be described in greater detail. However, it should be recognized that the preferred embodiments of the present invention are provided for illustration rather than limiting the present invention. In addition, the present invention can be practiced in a wide range of other embodiments besides those explicitly described, and the scope of the present invention is not expressly limited except as specified in the accompanying claims.

In order to gain more experts' knowledge during analog layout generation, the present invention describes a model training and a circuit recognition process to produce a new analog circuit structure (layout). The proposed algorithm includes two major stages: the model training by an artificial intelligence (AI) model and the circuit recognition described as the following. Embodiments of the present invention may be used in a variety of layout applications.

Utilizing a design repository containing legacy design schematics/netlists, the proposed method analyzes the design data of each sub-circuit, and stores the analyzed data in a sub-circuit library (database).

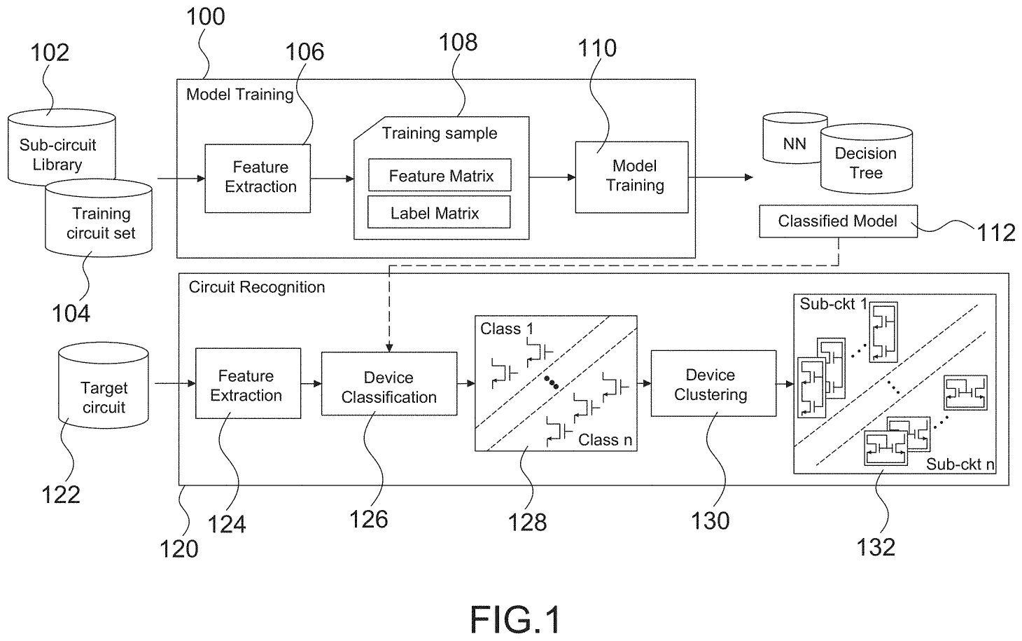

As shown in FIG. 1, a schematic diagram of a method for recognizing various analog circuit structures is described. The proposed algorithm includes two major stages: the model training 100 by an artificial intelligence (AI) model and the circuit recognition 120.

The method for recognizing various analog circuit structures in the invention comprises a step of preparing/inputting a complex analog circuit netlist and user-specified building blocks. A set of identified sub-circuits are outputted. For example, the netlist may be described in a Simulation Program with Integrated Circuit Emphasis (SPICE) format, and the design constraints are annotated into the netlist. Sub-circuits as analog circuit cells are identified as building blocks, which may refer to Wu et al., “A novel analog physical synthesis methodology integrating existent design expertise”, IEEE TCAD-2015. Each sub-circuit corresponds to some matched place-and-route (P&R) patterns which are chosen by a layout synthesizer.

In the stage of the model training 100, based on circuit information of the training circuit set, a process of a feature extraction 106 of the training circuit is performed by a feature extraction module to extract all sub-circuits for generating multiple training samples 108. Then, the training samples is classified by a model training procedure 110. For example, the model training is performed by a machine learning algorithm based on feature (characteristics) of the training samples 108. The training circuit set 104 is provided to train the neural network to classify training samples. The sub-circuit library (database) 102 provides building blocks data required for training circuit set 104. Then, the feature extraction 106 is performed by a feature extraction module to obtain training sample 108 through the training circuit inputting.

The training sample set is a set of training samples for training a classifier, such as decision tree classifier or neural network classifier, where the training sample includes a feature matrix and a label matrix corresponding to preset classification condition feature. The classifier is utilizing a classified model 112 (decision tree, neural network) to classify the training samples 108 in the training sample set according to the classification condition, and acquire a classification subset (classified building blocks). The classified building blocks are stored in the sub-circuit library (database) 102.

After the classification condition is determined, the training samples in the training sample set may be classified according to the classification condition or feature, so as to obtain a classification subset.

In the stage of the circuit recognition procedure 120, the schematic of the target circuit 122 is an input data. In the feature extraction 124, the schematic of the target circuit 122 is converted to be a corresponding connection graph or feature graph by the feature extraction module, and then the connection graph is encoded as a feature matrix. A unique matrix representation is applied to encode the connection graph or feature graph of the target circuit. Then, the device classification 126 procedure is performed by a classified model 112 to generate multiple groups of classified devices 128 based on the classified building blocks. Each building block of the groups of classified devices 128 is stored in the sub-circuit library (database) 102. Finally, the device clustering 130 procedure for the classified devices 128 is performed to acquire identified sub-circuits 132 to create an analog circuit structure.

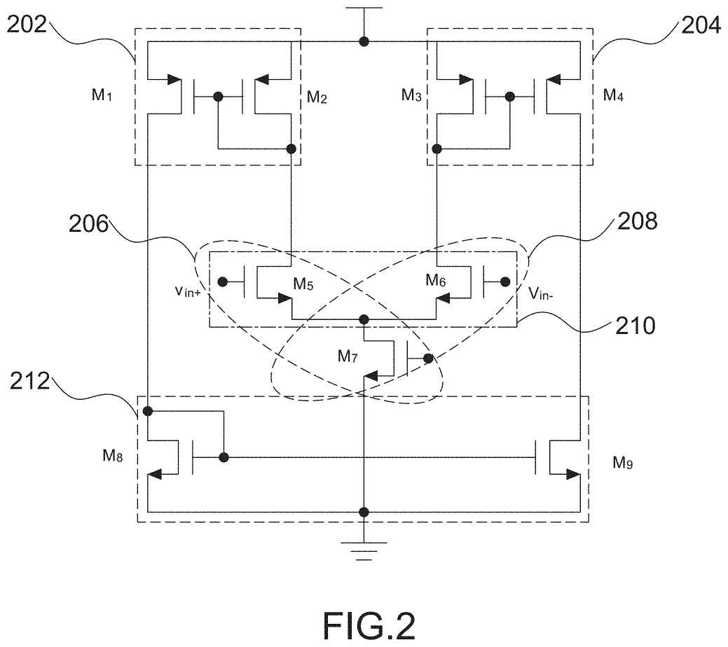

Given a set of legacy schematics and legacy layouts, a design database is first constructed based on a connection graph representation. Since a basic connection graph can only represent logical information corresponding to a schematic, some important physical information is further annotated from the corresponding legacy layout into the connection graph. A device type is tagged on each node. The target circuit is shown in FIG. 2 which shows the legacy schematic of an example CMOS cascade operational transconductance amplifier (OTA), which contains four PMOS transistors and five NMOS transistors. Each device could be included in different sub-circuits.

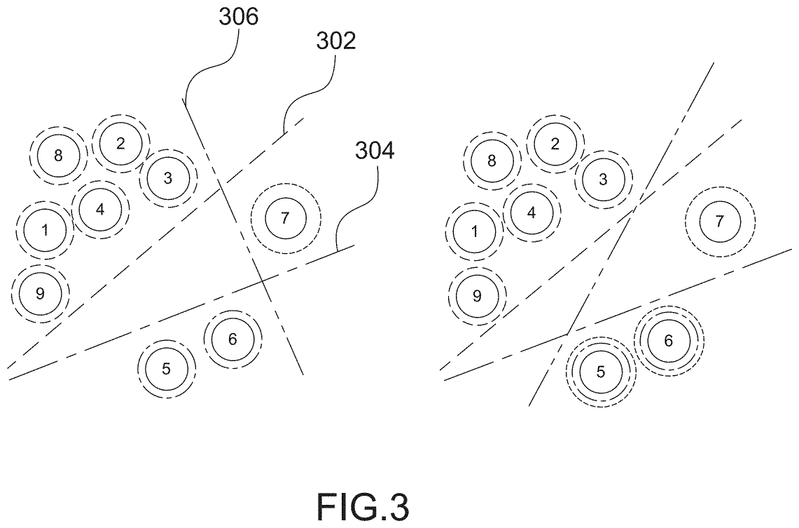

As shown in FIG. 3, node 1 represents PMOS device M1, node 2 represents PMOS device M2, node 3 represents PMOS device M3, and node 4 represents PMOS device M4. Similarly, node 5 represents NMOS device M5, node 6 represents NMOS device M6, node 7 represents NMOS device M7, node 8 represents NMOS device M8, and node 9 represents NMOS device M9. Each device could be included in different sub-circuits. Referring to FIG. 2, the PMOS device M1 and M2 are included in sub-circuit 202, and the PMOS device M3 and M4 are included in sub-circuit 204. Similarly, the NMOS device M5 and M7 are included in sub-circuit 206, the NMOS device M6 and M7 are included in sub-circuit 208, the NMOS device M5 and M6 are included in sub-circuit 210, and the NMOS device M8 and M9 are included in sub-circuit 212. The number 302, 304 and 306 indicates boundary of current mirror (cm), boundary of differential pair (dp) and boundary of cascode pair (cp), respectively.

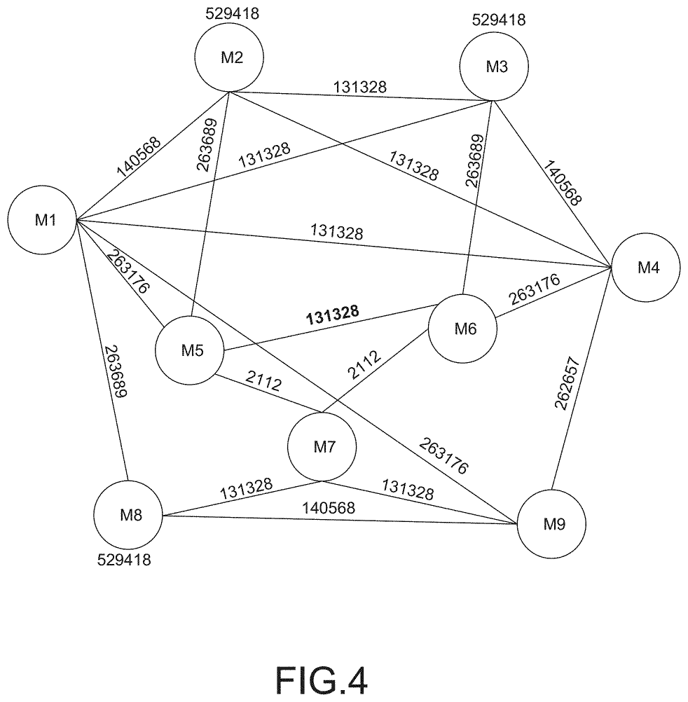

FIG. 4 illustrates a connection graph representation for the OTA in FIG. 2 according to an embodiment of the present invention. Similarly, all the other interconnection codes corresponding to each edge in the connection graph can be obtained, and the connection graph containing all interconnection codes is shown in FIG. 4. Each vertex represents a device. An edge exists between vertices if the devices are connected. For example, circuit function of the current mirror (cm) between the PMOS device M1 and the PMOS device M2, between the PMOS device M3 and the PMOS device M4, and between the NMOS device M8 and the NMOS device M9 has code number of 140568. The circuit function of the differential pair (dp) between the PMOS device M1 and the PMOS device M3, between the PMOS device M2 and the PMOS device M3, the PMOS device M1 and the PMOS device M4, the PMOS device M2 and the PMOS device M4, between the NMOS device M5 and the NMOS device M6, between the NMOS device M7 and the NMOS device M8, and between the NMOS device M7 and the NMOS device M9 has code number of 131328. The circuit function of the cascode pair (cp) between the NMOS device M5 and the NMOS device M7, and between the NMOS device M6 and the NMOS device M7 has code number of 2112. Code number of the vertices, the PMOS device M2, the PMOS device M3 and the NMOS device M8, is 528418. All features, including device types, circuit sizing, interconnection relationships, special connection to voltage/current sources, etc., are encoded. The code number of the feature graph between vertices is unique. That is, the feature graph with the code number is one-to-one mapping.

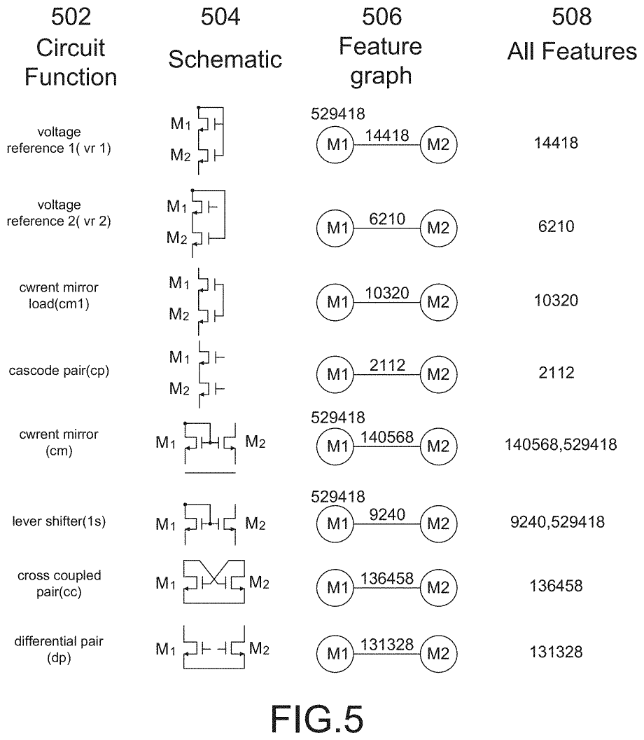

In the stage of the circuit recognition procedure, the schematic of the target circuit 122 is an input data. In the feature extraction 124, the schematic of the target circuit 122 is converted to be the corresponding connection graph by the feature extraction module, and the connection graph is encoded as a feature matrix. For example, as shown in FIG. 5, the schematic 504 of the target circuit (M1-M2) corresponds to the following circuit function 502: a voltage reference 1 (vr 1), a voltage reference 2 (vr 2), a current mirror load (cml), a cascode pair (cp), a current mirror (cm), a level shifter (ls), cross coupled pair (cc) and differential pair (dp) respectively, which can either be given by designers or automatically extracted. The schematic 504 of the target circuit is converted to the feature graph 506, and the feature (connection) graph is transferred as a feature matrix including all features 508, where each of all features is labelled by a number, including 14418, 6210, 10320, 2112, (140568, 529418), (9240, 529418), 136458 and 131328.

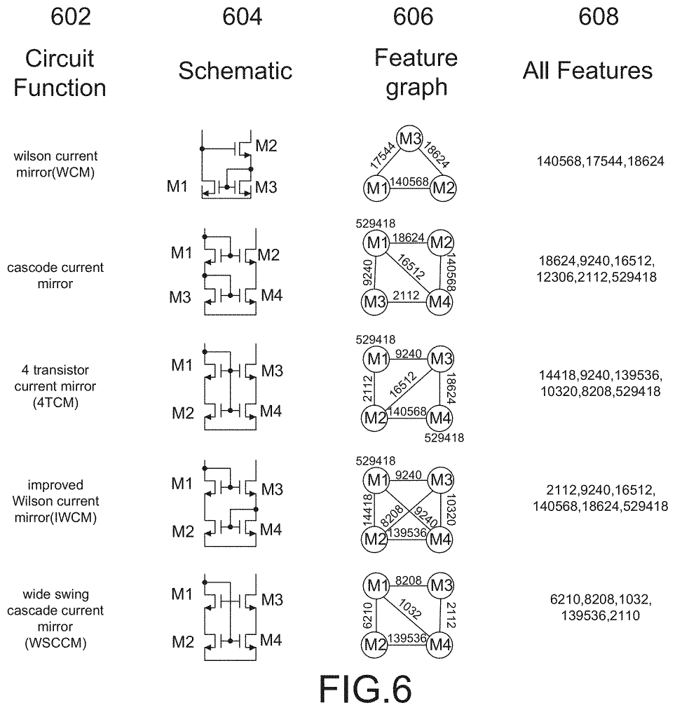

Similarly, as shown in FIG. 6, the schematic 604 of the target circuit (M1, M2, M3, M4) corresponds to the following circuit function 602: a Wilson current mirror load (WCM), a cascode current mirror, a 4 transistor current mirror (4TCM), an improved Wilson current mirror load (IWCM) and wide swing cascode current mirror (WSCCM) respectively, which can either be given by designers or automatically extracted. The schematic 604 of the target circuit is converted to the feature graph 606, and the feature (connection) graph is transferred (recorded) as a feature matrix including all features 608, where each of all features is labelled by a number, including (140528, 17544, 18624), (18624, 9240, 16512, 12306, 2112, 529418), (14418, 9240, 139536, 10320, 8208, 529418), (2112, 9240, 16512, 140568, 18624, 529418) and (6210, 8208, 1032, 139536, 2110).

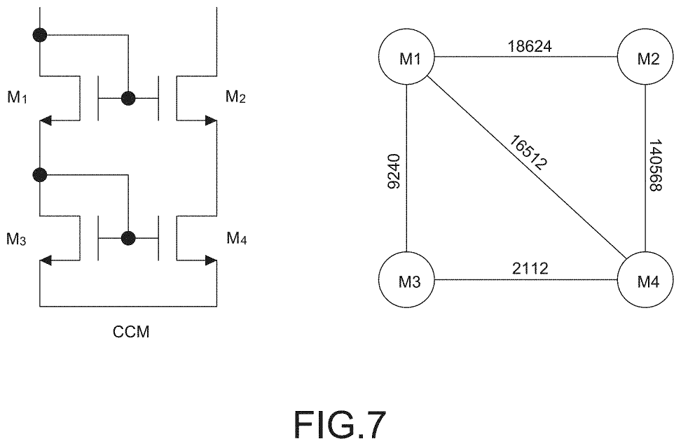

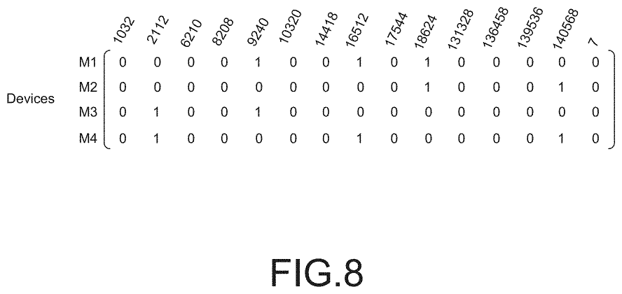

As shown in FIG. 7, it illustrates the schematic and the feature graph of 4 transistor current mirror (4TCM). Encoded features of 4 transistor in FIG. 7 is represented by the feature matrix, shown in FIG. 8, where the encoded feature graph is indicated by number 1032, 2112, 6210, 8208, 9240, 10320, 14418, 16512, 17544, 18624, 131328, 136458, 139s536, 140568 and 7. Each number can indicate an encoded feature between the devices M1, M2, M3 and M4.

The proposed method for the target circuit in which a computer performs processes of: extracting feature matrix of the target circuit; classifying the feature matrix to obtain multiple groups of classified devices; and clustering the classified devices to acquire identified sub-circuits. Therefore, a set of identified sub-circuits are outputted. The method for recognizing various analog circuit structures is finished.

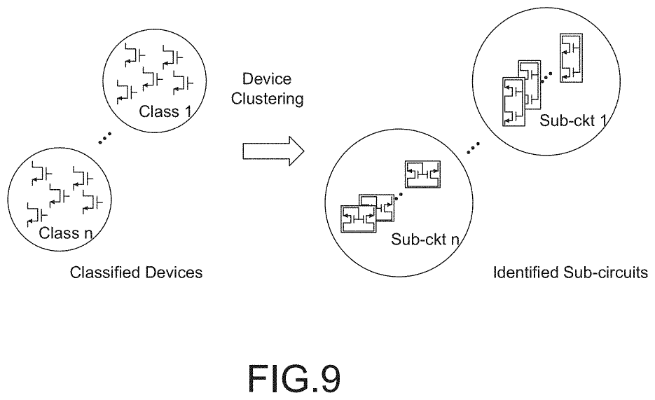

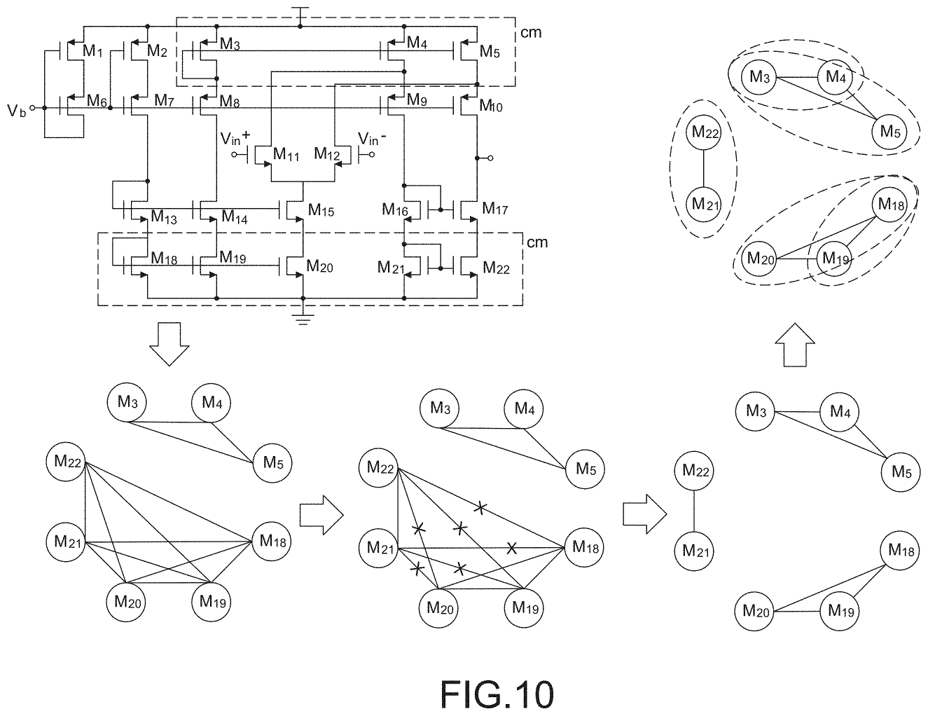

As shown in FIG. 9, the classified devices (class 1, . . . , class n) are clustered into sub-circuits (Sub-ckt 1, . . . , Sub-ckt n) according to resulting prediction matrix. For an example of device clustering for a target circuit in FIG. 10, the devices M3, M4 and M5 are included in a connection graph, and the devices M18, M19, M20, M21 and M22 are included into another connection graph. Regardless of the connection “cross X” between the devices M18, M19, M20, M21 and M22, two connection graphs are inverted into three connection graphs. Accordingly, two type of sub-circuits are generated by device clustering, where the devices M3 and M4 are included in a first type sub-circuit and a second type sub-circuit, and the devices M18 and M19 are also included in the first type sub-circuit and the second type sub-circuit.

According to the invention, the machine learning algorithm includes a feature extraction process and a classification model.

The method further comprises providing a database for the machine learning algorithm. The machine learning algorithm includes at least one neural network and at least one classifier.

In the invention, a model training is performed by a machine learning algorithm to analyze and judge the feature graph of training sample, so as to automatically classify the type of the building blocks. For example, a classifier is used to automatically identify the type of the building blocks.

The algorithms of the machine learning can be executed by operation of computer. The experimental results show that the proposed method can successfully classify the training circuit, and achieve the accuracy rate of detection and classification 96% and 97% respectively, even higher accuracy.

In the present invention, the proposed algorithm may be implemented in the following experimental setup: programming language “Python 3.4”, library “Scikit-learn”, platform “2.6 GHz Intel CPU, GTX-1080 Ti GPU”, training circuits “textbooks, papers in the literature”, total training sample “385 circuits, 13580 devices”, training and testing ratio “90%:10%” and test circuits including “Folded Cascode OpAmp, Buffer Amp, Chopper OpAmp”, where Folded Cascode OpAmp uses twenty-two number of devices and twenty-seven number of sub-circuits, Buffer Amp uses forty-two number of devices and forty-one number of sub-circuits, and Chopper OpAmp uses one hundred-sixty number of devices and one hundred-sixteen number of sub-circuits.

Experimental results show in table 1. Compared with the graph-based deterministic approach, the proposed ML approach based on decision tree results in 8.5X runtime improvement without sacrificing accuracy. That is, the proposed framework achieves 8.5 speedup than the previous method.

TABLE 1

| | | | Graph-based | | | | | | |
|---|---|---|---|---|---|---|---|---|---|
| Target Circuit | | | Deterministric Approach | | Proposed ML Approach based on Decision Tree | | | | |
| | # | # Sub- | # identified | Time | # identified | Time (sec) | | | |
| Name | Device | circuit | sub-circuits | (sec) | sub-circuits | Setup | Prediction | Clustering | Total |
| Folded Cascode | 22 | 27 | 27 | 0.075 | 27 | 0.007 | 0.006 | 0.010 | 0.023 |
| OpAmp | | | | | | | | | |
| Buffer Amp | 42 | 41 | 41 | 0.260 | 41 | 0.016 | 0.006 | 0.053 | 0.075 |
| Chopper OPA | 160 | 116 | 112 | 2.335 | 112 | 0.059 | 0.023 | 0.024 | 0.106 |

| | | |
|---|---|---|
| Comparison | 8.585 | 1 |

As will be understood by persons skilled in the art, the foregoing preferred embodiment of the present invention illustrates the present invention rather than limiting the present invention. Having described the invention in connection with a preferred embodiment, modifications will be suggested to those skilled in the art. Thus, the invention is not to be limited to this embodiment, but rather the invention is intended to cover various modifications and similar arrangements included within the spirit and scope of the appended claims, the scope of which should be accorded the broadest interpretation, thereby encompassing all such modifications and similar structures. While the preferred embodiment of the invention has been illustrated and described, it will be appreciated that various changes can be made without departing from the spirit and scope of the invention.

1. A non-transitory computer-readable medium containing instructions, which when read and executed by a computer, cause the computer to execute a method for recognizing various analog circuit structures, wherein the method comprises steps of:
performing a first feature extraction of a training circuit to extract all sub-circuits for generating multiple training samples;
classifying said multiple training samples by a classifier to obtain a plurality of building blocks;
performing a second feature extraction of each device of a target circuit to convert as a connection graph;
recognizing said connection graph of said each device of said target circuit to belong to which of said plurality of building blocks by said classifier such that a first device of said target circuit is included in different building blocks of said plurality of building blocks;
classifying first connection graphs of all devices of said target circuit into second connection graphs to obtain multiple groups of classified devices, wherein a first number of said first connection graphs is different from a second number of said second connection graphs; and
clustering each group of said multiple groups of classified devices which belongs to an identical building block of said classified building blocks to acquire identified sub-circuits.

2. The non-transitory computer-readable medium of claim 1, further comprising storing said classified building blocks in a sub-circuit library.

3. The non-transitory computer-readable medium of claim 1, wherein said classifier is used to automatically identify a type of each of said all building blocks.

4. The non-transitory computer-readable medium of claim 1, wherein said multiple training samples comprises a feature matrix and a label matrix.

5. The non-transitory computer-readable medium of claim 1, wherein said classifier is utilizing a classified model to classify said multiple training samples in a training sample set.

6. The non-transitory computer-readable medium of claim 5, wherein said classified model includes decision tree or neural network.

7. The non-transitory computer-readable medium of claim 5, wherein said classified model is performed by a machine learning algorithm.

8. The non-transitory computer-readable medium of claim 7, wherein said machine learning algorithm includes a feature extraction process and said classified model.

9. The non-transitory computer-readable medium of claim 1, wherein said encoded feature graph is indicated by a number.

10. The non-transitory computer-readable medium of claim 9, wherein said encoded feature graph with said number is one-to-one mapping.

11. A method for recognizing various analog circuit structures, which is executed by a computer, the method comprising:
using the computer to perform the following:
performing a first feature extraction of a training circuit to extract all sub-circuits for generating multiple training samples;
classifying said multiple training samples by a classifier to obtain classified building blocks;
performing a second feature extraction of each device of a target circuit to convert as a connection graph;
recognizing said connection graph of said each device of said target circuit to belong to which of said plurality of building blocks by said classifier such that a first device of said target circuit is included in different building blocks of said plurality of building blocks;
classifying first connection graphs of all devices of said target circuit into second connection graphs to obtain multiple groups of classified devices, wherein a first number of said first connection graphs is different from a second number of said second connection graphs; and
clustering each group of said multiple groups of classified devices which belongs to an identical building block of said classified building blocks to acquire identified sub-circuits.

12. The method of claim 11, further comprising storing said classified building blocks in a sub-circuit library.

13. The method of claim 11, wherein said classifier is used to automatically identify a type of each of said all building blocks.

14. The method of claim 11, wherein said multiple training samples comprises a feature matrix and a label matrix.

15. The method of claim 11, wherein said classifier is utilizing a classified model to classify said multiple training samples in a training sample set.

16. The method of claim 15, wherein said classified model includes decision tree or neural network.

17. The method of claim 15, wherein said classified model is performed by a machine learning algorithm.

18. The method of claim 17, wherein said machine learning algorithm includes a feature extraction process and said classified model.

19. The method of claim 11, wherein said encoded feature graph is indicated by a number.

20. The method of claim 19, wherein said encoded feature graph with said number is one-to-one mapping.
